(19) United States
(12) Patent Application Publication
(10) Pub. No.: US 2022/0139776 A1
(43) Pub. Date: May 5, 2022

(54) METHOD FOR FILLING RECESSED FEATURES IN SEMICONDUCTOR DEVICES WITH A LOW-RESISTIVITY METAL

(71) Applicant: Tokyo Electron Limited, Tokyo (JP)

(72) Inventors: Kai-Hung Yu, Albany, NY (US); David L. O'Meara, Albany, NY (US); Hisashi Higuchi, Albany, NY (US); Hirokazu Aizawa, Albany, NY (US); Omid Zandi, Albany, NY (US); Cory Wajda, Albany, NY (US); Gerrit J. Leusink, Albany, NY (US)

(21) Appl. No.: 17/507,136

(22) Filed: Oct. 21, 2021

Related U.S. Application Data
(60) Provisional application No. 63/109,332, filed on Nov. 3, 2020.

(51) Int. Cl. H01L 21/768; H01L 21/285

(52) U.S. Cl. CPC H01L 21/76879; H01L 21/28556; H01L 21/76846; H01L 21/76864; H01L 21/76888; H01L 21/76826

(57) ABSTRACT

A method for filling recessed features with a low-resistivity metal includes providing a patterned substrate containing a recessed feature formed in a first layer and a second layer that is exposed in the recessed feature, pre-treating the substrate with a surface modifier that increases metal deposition selectivity on the second layer relative to on the first layer, and depositing a metal layer on the substrate by vapor phase deposition, where the metal layer is preferentially deposited on the second layer in the recessed feature. The method further includes removing metal nuclei deposited on the first layer, including on a field area and on sidewalls of the first layer in the recessed feature, to selectively form the metal layer on the second layer in the recessed feature, where the removing includes exposing the patterned substrate to an etching gas containing ozone.

This application is related to and claims priority to U.S. Provisional Patent Application Ser. No. 63/109,332 filed on Nov. 3, 2020, the entire contents of which are herein incorporated by reference.

### FIELD OF THE INVENTION

The present invention relates to semiconductor processing and semiconductor devices, and more particularly, to a method for filling recessed features in semiconductor devices with a low-resistivity metal.

### BACKGROUND OF THE INVENTION

Semiconductor devices contain filled recessed features such as trenches or vias that are formed in a dielectric material such as an interlayer dielectric (ILD). Selective metal filling of the recessed features is problematic due to finite metal deposition selectivity on a metal layer at the bottom of the recessed features relative to on the dielectric material. This makes it difficult to fully fill the recessed features with a metal in a bottom-up deposition process before the on-set of unwanted metal nuclei deposition on the field area (horizontal area) around the recessed features and on the sidewalls of the recessed features.

### SUMMARY OF THE INVENTION

Embodiments of the invention describe a method of filling recessed features in semiconductor devices with a low-resistivity metal. According to one embodiment, the method includes providing a patterned substrate containing a recessed feature formed in a first layer and a second layer that is exposed in the recessed feature, and pre-treating the substrate with a surface modifier that increases metal deposition selectivity on the second layer relative to on the first layer. The method further includes depositing a metal layer on the substrate by vapor phase deposition, where the metal layer is preferentially deposited on the second layer in the recessed feature, and removing metal nuclei deposited on the first layer, including on a field area and on sidewalls of the first layer in the recessed feature, where the removing includes exposing the patterned substrate to an etching gas containing ozone, to selectively form the metal layer on the second layer in the recessed feature. The steps of depositing and removing may be repeated at least once to increase a thickness of the metal layer in the recessed feature.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIGS. 1A-1F schematically show a method for selective metal formation in a recessed feature according to an embodiment of the invention; and

FIGS. 2A-2G schematically show a method for selective metal formation in a recessed feature according to another embodiment of the invention.

### DETAILED DESCRIPTION OF SEVERAL EMBODIMENTS

Embodiments of the invention provide a method for selectively forming a low-resistivity metal in recessed features of a semiconductor device. The method can be used to fully fill the recessed features with the low-resistivity metal. The deposited metal can, for example, include ruthenium (Ru) metal, cobalt (Co) metal, or tungsten (W) metal.

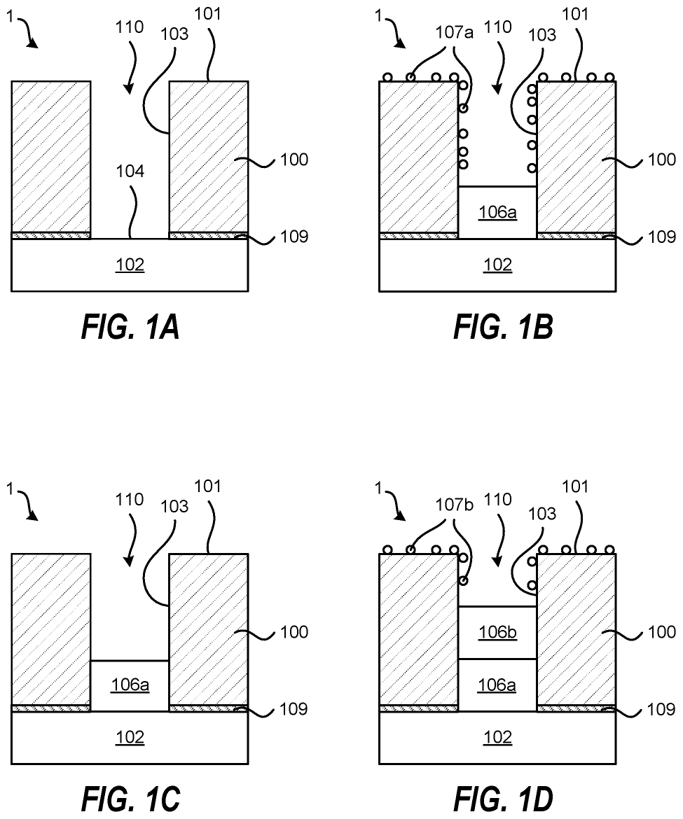

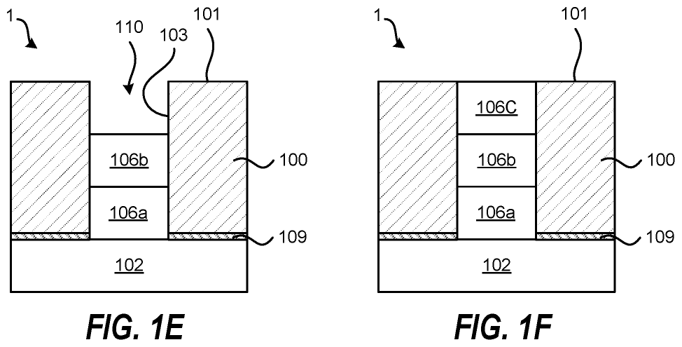

FIGS. 1A-1F schematically shows a method for selective metal formation in a recessed feature according to an embodiment of the invention. The metal can, for example, be selected from the group consisting of Ru metal, Co metal, and W metal. The patterned substrate 1 contains a field area 101 around a recessed feature 110 that is formed in a first layer 100. The recessed feature 110 contains sidewalls 103 and a second layer 102 that has an exposed surface 104. The patterned substrate 1 further includes an etch stop layer 109.

According to one embodiment, the first layer 100 can include a dielectric material and the second layer 102 can include a metal layer. The dielectric material can, for example, contain SiO₂, a low dielectric constant (low-k) material such as fluorinated silicon glass (FSG), carbon doped oxide, a polymer, a SiCOH-containing low-k material, a non-porous low-k material, a porous low-k material, a CVD low-k material, a spin-on dielectric (SOD) low-k material, or any other suitable dielectric material, including a high dielectric constant (high-k) material. In some examples, a width (critical dimension (CD)) of the recessed feature 110 can be between about 10 nm and about 100 nm, between about 10 nm and about 15 nm, between about 20 nm and about 90, or between about 40 nm and about 80 nm. In some examples, the depth of the recessed feature 110 can between bout 40 nm and about 200 nm, between about 50 nm and about 150, or between about 50 nm and about 150 nm. In some examples, and the recessed feature 110 can have an aspect ratio (depth/width) between about 2 and about 20, or between about 4 and about 6. The second layer 102 can include a low-resistivity metal such as Cu metal, Ru metal, Co metal, W metal, or a combination thereof. In one example, the second layer 102 can include two or more stacked metal layers. Examples of the stacked metal layers include Co metal on Cu metal (Co/Cu) and Ru metal on Cu metal (Ru/Cu). In one example, the first layer 100 contains SiO₂ and the second layer 102 includes a W metal layer, a structure commonly found in middle-of-line (MOL) region of a semiconductor device.

The method includes an optional pre-cleaning step that includes exposing the patterned substrate 1 to a H₂-containing gas to chemically reduce the exposed surface 104 of the second layer 102. For example, the H₂-containing gas can consist of H₂ gas, or can contain H₂ gas and Ar gas. The pre-cleaning step may be performed with or without plasma excitation of the H₂-containing gas. In one example, the pre-cleaning includes exposing the patterned substrate 1 to H₂ gas and Ar gas at a substrate temperature between about 250° C. and about 400° C., at a gas pressure between about 250 mTorr and about 7 Torr, and for a time period between about 30 seconds and about 60 seconds. In some examples, the second layer 102 contains Cu metal or W metal and the pre-cleaning step chemically reduces CuOₓ or WOₓ surface species to the corresponding elementary metal and subsequentially reduces the electrical resistance in the final device.

to form a layer 213 that increases metal deposition selectivity on the second layer 202 relative to on the first layer 200

The method further includes pre-treating the patterned substrate 1 with a surface modifier that adsorbs on the first layer 100 to form a layer (not shown) that increases metal deposition selectivity on the second layer 102 relative to on the first layer 100, including on the sidewalls 103 and on the field area 101 of the first layer 100. The presence of the surface modifier hinders or delays deposition of the metal layer on first layer 100 through physical blocking but the second layer 102 is not modified. According to one embodiment, the patterned substrate 1 is pre-treated with a surface modifier by exposure to a reactant gas that contains a molecule that is capable of forming self-assembled monolayers (SAMs) on a substrate. SAMs are molecular assemblies that are formed spontaneously on substrate surfaces by adsorption and are organized into more or less large ordered domains. The SAMs can include a molecule that possesses a head group, a tail group, and a functional end group, and SAMs are created by the chemisorption of head groups onto the substrate from the vapor phase at room temperature or above room temperature, followed by a slow organization of the tail groups. Initially, at small molecular density on the surface, adsorbate molecules form either a disordered mass of molecules or form an ordered two-dimensional “lying down phase”, and at higher molecular coverage, over a period of minutes to hours, begin to form three-dimensional crystalline or semicrystalline structures on the substrate surface. The head groups assemble together on the substrate, while the tail groups assemble far from the substrate. According to one embodiment, the head group of the molecule forming the SAMs can include a thiol, a silane, or a phosphonate. Examples of silanes include molecule that include C, H, Cl, F, and Si atoms, or C, H, Cl, and Si atoms. Non-limiting examples of the molecule include perfluorodecyltrichlorosilane (CF₃(CF₂)₇CH₂CH₂SiCl₃), perfluorodecanethiol (CF₃(CF₂)₇CH₂CH₂SH), chlorodecyldimethylsilane (CH₃(CH₂)₈CH₂Si(CH₃)₂Cl), and tertbutyl(chloro)dimethylsilane ((CH₃)₃CSi(CH₃)₂Cl)).

According to some embodiments of the invention, the reactant gas can contain a silicon-containing gas, including an alkyl silane, an alkoxysilane, an alkyl alkoxysilane, an alkyl siloxane, an alkoxysiloxane, an alkyl alkoxysiloxane, an aryl silane, an acyl silane, an aryl siloxane, an acyl siloxane, a silazane, or any combination thereof. According to some embodiments of the invention, the reactant gas may be selected from dimethylsilane dimethylamine (DMSDMA), trimethylsilane dimethylamine (TMSDMA), bis(dimethylamino) dimethylsilane (BDMADMS), and other alkyl amine silanes. According to other embodiments, the reactant gas may be selected from N,O bistrimethylsilyltrifluoroacetamide (BSTFA) and trimethylsilyl-pyrrole (TMS-pyrrole).

According to some embodiments of the invention, the reactant gas may be selected from silazane compounds. Silazanes are saturated silicon-nitrogen hydrides. They are analogous in structure to siloxanes with —NH— replacing —O—. An organic silazane precursor can further contain at least one alkyl group bonded to the Si atom(s). The alkyl group can, for example, be a methyl group, an ethyl group, a propyl group, or a butyl group, or combinations thereof. Furthermore, the alkyl group can be a cyclic hydrocarbon group such as a phenyl group. In addition, the alkyl group can be a vinyl group. Disilazanes are compounds having from 1 to 6 methyl groups attached to the silicon atoms or having 1 to 6 ethyl groups attached the silicon atoms, or a disilazane molecule having a combination of methyl and ethyl groups attached to the silicon atoms.

The method further includes depositing a metal layer 106a on the patterned substrate 1 by vapor phase deposition, where the metal layer 106a is preferentially deposited on the second layer 102 in the recessed feature 110. The metal layer 106a can, for example, be selected from the group consisting of Ru metal, Co metal, and W metal. According to one embodiment of the invention, Ru metal may be deposited by chemical vapor phase deposition (CVD) or atomic layer deposition (ALD). Examples of Ru-containing precursors include Ru₃(CO)₁₂, (2,4-dimethylpentadienyl) (ethylcyclopentadienyl) ruthenium (Ru(DMPD)(EtCp)), bis(2,4-dimethylpentadienyl) ruthenium (Ru(DMPD)₂), 4-dimethylpentadienyl) (methylcyclopentadienyl) ruthenium (Ru(DMPD)(MeCp)), and bis(ethylcyclopentadienyl) ruthenium (Ru(EtCp)₂), as well as combinations of these and other precursors.

In one example, Ru metal is deposited by CVD using a Ru₃(CO)₁₂ precursor in a CO carrier gas at a substrate temperature between about 120° C. and about 250° C., gas pressure between about 5 mTorr and about 500 mTorr, and a gas exposure time between about 100 seconds and about 200 seconds.

As schematically shown in FIG. 1B, the metal deposition may not be completely selective and metal nuclei 107a may be deposited on the sidewalls 103 and on the field area 101 of the first layer 100. Unlike the metal layer 106a, the metal nuclei 107a may be form a non-continuous layer of metal where the total amount of the metal in the metal nuclei 107a is less than the amount of the metal in the metal layer 106a.

The method further includes an optional first heat-treating step that includes exposing the patterned substrate 1 in FIG. 1B to a H₂-containing gas. For example, the H₂-containing gas can consist of H₂ gas, or can contain H₂ gas and Ar gas. The first heat-treating step may be performed with or without plasma excitation of the H₂-containing gas. In one example, the pre-cleaning includes exposing the patterned substrate 1 to H₂ gas and Ar gas at a substrate temperature between about 300° C. and about 350° C., at a gas pressure between about 250 mTorr and about 7 Torr, and for a time period between about 30 seconds and about 60 seconds. In one example, the metal layer 106a contains Ru metal deposited by CVD using a Ru₃(CO)₁₂ precursor in a CO carrier gas and the optional first heat-treating step removes adsorbed CO surface species from the deposited Ru metal to aid in the subsequent removal of the Ru metal nuclei 107a.

The method further includes removing the metal nuclei 107a from the patterned substrate 1 to selectively form the metal layer 106a on the second layer 102 in the recessed feature 110 and not on the sidewalls 103 and on the field area 101 of the first layer 100. This is schematically shown in FIG. 1C. It may be preferable to pause the metal deposition and perform the removal of the metal nuclei 107a before they get too big and are more difficult to remove efficiently. In one example, Ru metal nuclei 107a may be removed by etching, for example using an etching gas containing ozone (O₃) and a carrier gas. The etching gas containing O₃ may be generated by plasma excitation in the process chamber containing the patterned substrate 1 or, alternately, the etching gas containing O₃ may be generated remotely using an ozone generator and flowed into the process chamber where it is exposed to the patterned substrate 1. Analysis of the patterned substrate 1 following an exposure to an etching gas containing O₃ showed little or no damage to the dielectric material of the first layer 100. This is in contrast with the use of plasma excited etching gases with high-kinetic energy ions that impact the patterned substrate 1 to remove the nuclei 107a. Further, it was observed that the exposure to the etching gas containing O₃ did not substantially remove the surface modifier (e.g., a SAM) from the first layer 100. This allows for optional re-application of the surface modifier when the process sequence is repeated.

The method further includes an optional second heat-treating step that includes exposing the patterned substrate 1 in FIG. 1C to a H₂-containing gas to chemically reduce the exposed surface of the metal layer 106a following the exposure to the etching gas. For example, the H₂-containing gas can consist of H₂ gas, or contain H₂ gas and Ar gas. The optional second heat-treating step may be performed with or without plasma excitation of the H₂-containing gas. In one example, the pre-cleaning includes exposing the patterned substrate 1 to H₂ gas and Ar gas at a substrate temperature between about 300° C. and about 350° C., at a gas pressure between about 250 mTorr and about 7 Torr, and for a time period between about 30 seconds and about 60 seconds. In one example, the metal layer 106a contains Ru metal and the optional second heat-treating step chemically reduces RuOₓ surface species to the corresponding Ru elementary metal.

According to one embodiment, the steps of depositing a metal layer and removing metal nuclei may be repeated at least once to increase a thickness of the metal layer 106a selectively formed on the second layer 102 in the recessed feature 110. This is schematically shown in FIG. 1D, where an additional metal layer 106b is preferentially deposited on the metal layer 106a and additional metal nuclei 107b are deposited on the sidewalls 103 and on the field area 101. Thereafter, as shown in FIG. 1E, the additional metal nuclei 107b are removed. In one example, the depositing and removing steps may be repeated until the recessed feature 110 is fully filled with the metal. This is schematically shown in FIG. 1F, where the recessed feature 110 is filled with metal layers 106a-106c and the field area 101 is at least substantially free of the deposited metal. According to other embodiments, the method can further include further repeating one or more of the steps of pre-cleaning, pre-treating, first heat-treating, and second heat-treating.

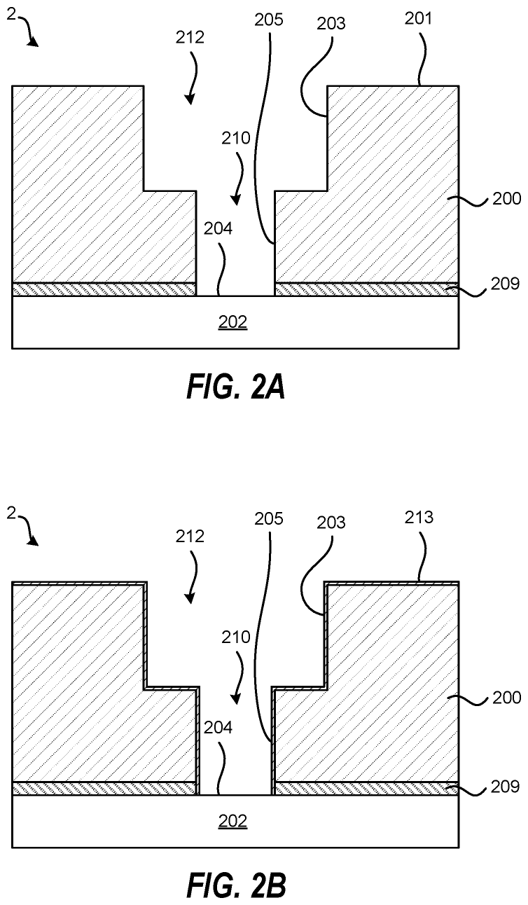

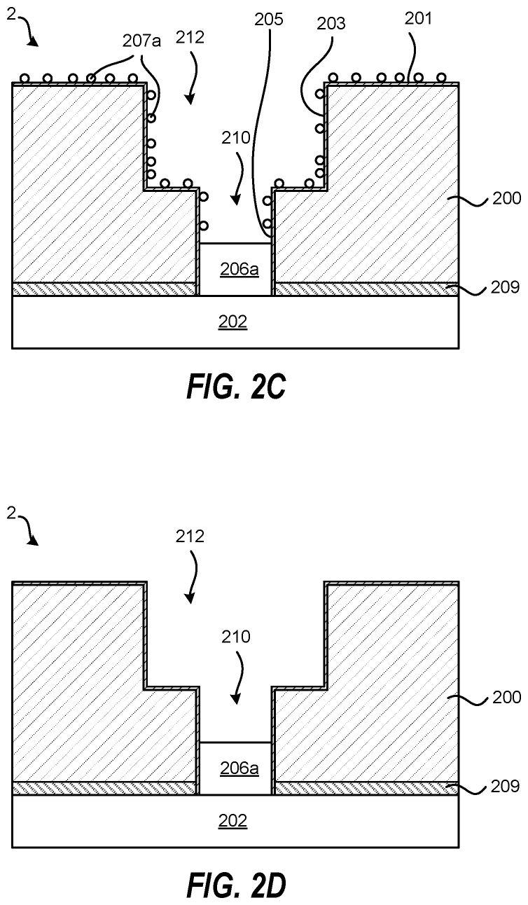

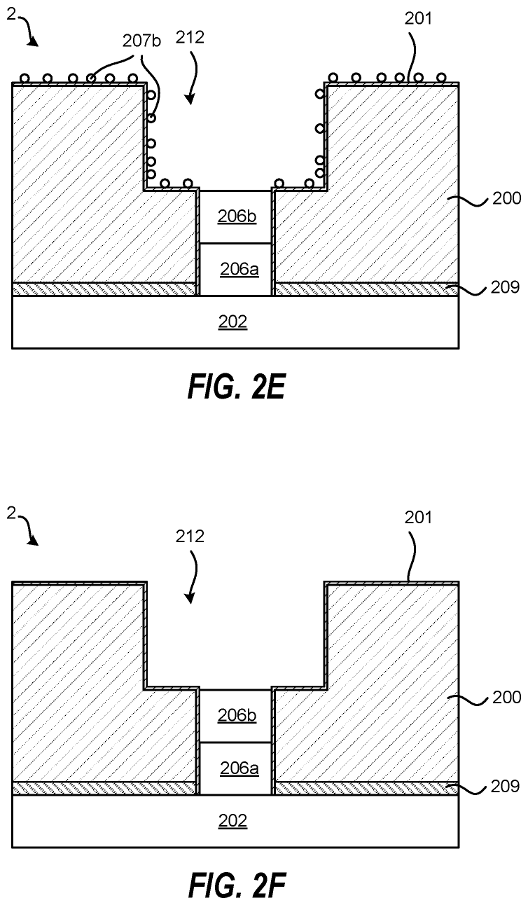

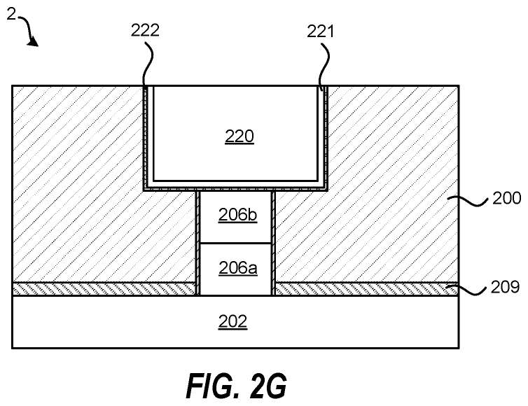

FIGS. 2A-2G schematically shows a method for selective metal formation in a recessed feature according to another embodiment of the invention. The patterned substrate 2 shown in FIG. 2A is similar to the patterned substrate 1 and contains a field area 201 around a recessed features 210 (e.g., a via) and 211 (e.g., a trench) formed in a first layer 200. The recessed feature 212 contains sidewalls 203 and the recessed feature 210 contains sidewalls 205 and a second layer 102 that has an exposed surface 204 at the bottom of the recessed feature 210. The patterned substrate 2 further includes an etch stop layer 209. In one example, the first layer 200 contains a low-k material and the second layer 102 includes a Cu metal layer. This structure commonly found in backend-of-line (BEOL) region of a semiconductor device.

The method includes an optional pre-cleaning step that includes exposing the patterned substrate 2 to a H₂-containing gas to chemically reduce the exposed surface 204 of the second layer 202. The method further includes pre-treating the patterned substrate 2 with a surface modifier that adsorbs on the first layer 200 to form a layer 213 that increases metal deposition selectivity on the second layer 202 relative to on the first layer 200, including on the sidewalls 203 and 205 and on the field area 201. This is schematically shown in FIG. 2B.

The method further includes depositing a metal layer 206a on the patterned substrate 2 by vapor phase deposition, where the metal layer 206a is preferentially deposited on the second layer 202 in the recessed feature 210. As schematically shown in FIG. 2C, the metal deposition may not be completely selective and metal nuclei 207a may be deposited on the sidewalls 203, 205 and on the field area 201 of the first layer 200.

The method further includes an optional first heat-treating step that includes exposing the patterned substrate 2 to a H₂-containing gas. In one example, the step removes adsorbed CO surface species from deposited Ru metal to aid in the subsequent removal of Ru metal nuclei 207a. The method further includes removing the metal nuclei 207a from the patterned substrate 2 to selectively form the metal layer 206a on the second layer 202 in the recessed feature 210. The method further includes an optional second heat-treating step that includes exposing the patterned substrate 2 to a H₂-containing gas to chemically reduce the exposed surface 204 of the metal layer 206a.

According to one embodiment, the steps of depositing a metal layer and removing metal nuclei may be repeated at least once to increase a thickness of the metal deposited in the recessed feature 210. An additional metal layer 206b is preferentially deposited on the metal layer 206a and additional metal nuclei 207b are deposited on the sidewalls 203, 205 and on the field area 201. This is schematically shown in FIG. 2E. Thereafter, as shown in FIG. 2F, the additional metal nuclei 207b are removed. According to other embodiments, the method can further include further repeating one or more of the steps of pre-cleaning, pre-treating, first heat-treating, and second heat-treating.

Thereafter, the patterned substrate 2 may be further processed. In one example, the further processing includes depositing a conformal barrier layer 222, depositing a nucleation layer 221, filling the recessed feature 212 with a metal 220 (e.g., Cu metal), and performing a planarization process (e.g., chemical mechanical polishing (CMP)) to form the structure shown in FIG. 2G.

A method for filling recessed features in semiconductor devices with a low-resistivity metal has been disclosed in various embodiments. The foregoing description of the embodiments of the invention has been presented for the purposes of illustration and description. It is not intended to be exhaustive or to limit the invention to the precise forms disclosed. This description and the claims following include terms that are used for descriptive purposes only and are not to be construed as limiting. Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

What is claimed is:

1. A method of forming a semiconductor device, the method comprising:
providing a patterned substrate containing a recessed feature formed in a first layer and a second layer that is exposed in the recessed feature;
pre-treating the substrate with a surface modifier that increases metal deposition selectivity on the second layer relative to on the first layer;
depositing a metal layer on the substrate by vapor phase deposition, where the metal layer is preferentially deposited on the second layer in the recessed feature; and
removing metal nuclei deposited on the first layer, including on a field area and on sidewalls of the first layer in the recessed feature, to selectively form the metal layer on the second layer in the recessed feature, wherein the removing includes exposing the patterned substrate to an etching gas containing ozone.

2. The method of claim 1, further comprising:
repeating the depositing and removing at least once to increase a thickness of the metal layer in the recessed feature.

3. The method of claim 1, wherein the metal layer fully fills the recessed feature.

4. The method of claim 3, wherein the field area is at least substantially free of the deposited metal.

5. The method of claim 1, wherein the pre-treating includes exposing the patterned substrate to a reactant gas containing a molecule that is capable of forming self-assembled monolayers (SAMs) on the patterned substrate.

6. The method of claim 1, wherein the pre-treating includes exposing the patterned substrate to a reactant gas containing an alkyl silane, an alkoxysilane, an alkyl alkoxysilane, an alkyl siloxane, an alkoxysiloxane, an alkyl alkoxysiloxane, an aryl silane, an acyl silane, an aryl siloxane, an acyl siloxane, a silazane, or any combination thereof.

7. The method of claim 1, wherein the second layer is selected from the group consisting of Ru metal, Co metal, and W metal, and the metal layer is selected from the group consisting of Cu metal, Ru metal, Co metal, W metal, and a combination thereof.

8. The method of claim 1, further comprising:
performing a pre-cleaning step that includes exposing the patterned substrate to a H₂-containing gas to chemically reduce an exposed surface of the second layer.

9. The method of claim 1, wherein the metal layer includes Ru metal deposited using a Ru₃(CO)₁₂ precursor in a CO carrier gas, the method further comprising:
performing a first heat-treating step that includes exposing the metal layer to a H₂-containing gas to removes adsorbed CO surface species from the metal layer.

10. The method of claim 1, further comprising:
after the removing, performing a second heat-treating step that includes exposing the metal layer to a H₂-containing gas to chemically reduce an exposed surface of the metal layer.

11. The method of claim 1, wherein the recessed feature includes a trench and a via.

12. A method of forming a semiconductor device, the method comprising:
providing a patterned substrate containing a recessed feature formed in a first layer and a second layer that is exposed in the recessed feature;
performing a pre-cleaning step that includes exposing the patterned substrate to a H₂-containing gas to chemically reduce an exposed surface of the second layer;
pre-treating the substrate with a surface modifier that increases Ru metal deposition selectivity on the second layer relative to on the first layer;
depositing a Ru metal layer on the substrate by vapor phase deposition using a Ru₃(CO)₁₂ precursor in a CO carrier gas, where the Ru metal layer is preferentially deposited on the second layer in the recessed feature; and
removing Ru metal nuclei deposited on the first layer, including on a field area and on sidewalls of the first layer in the recessed feature, to selectively form the Ru metal layer on the second layer in the recessed feature, wherein the removing includes exposing the patterned substrate to an etching gas containing ozone.

13. The method of claim 12, further comprising:
repeating the depositing and removing at least once to increase a thickness of the Ru metal layer in the recessed feature.

14. The method of claim 13, wherein the Ru metal layer fully fills the recessed feature.

15. The method of claim 12, wherein the pre-treating includes exposing the patterned substrate to a reactant gas that contains a molecule that is capable of forming self-assembled monolayers (SAMs) on the patterned substrate.

16. The method of claim 12, wherein the pre-treating includes exposing the patterned substrate to a reactant gas containing an alkyl silane, an alkoxysilane, an alkyl alkoxysilane, an alkyl siloxane, an alkoxysiloxane, an alkyl alkoxysiloxane, an aryl silane, an acyl silane, an aryl siloxane, an acyl siloxane, a silazane, or any combination thereof.

17. The method of claim 12, wherein the second layer is selected from the group consisting of Ru metal, Co metal, and W metal.

18. The method of claim 12, wherein the recessed feature includes a trench and a via.

19. A method of forming a semiconductor device, the method comprising:
providing a patterned substrate containing a recessed feature formed in a first layer and a second layer that is exposed in the recessed feature;
performing a pre-cleaning step that includes exposing the patterned substrate to a H₂-containing gas to chemically reduce an exposed surface of the second layer;
pre-treating the substrate with a surface modifier that increases Ru metal deposition selectivity on the second layer relative to on the first layer, wherein the pre-treating includes exposing the patterned substrate to a reactant gas that contains a molecule that is capable of forming self-assembled monolayers (SAMs) on the patterned substrate;
depositing a Ru metal layer on the substrate by vapor phase deposition using a Ru₃(CO)₁₂ precursor in a CO carrier gas, where the Ru metal layer is preferentially deposited on the second layer in the recessed feature;
performing a first heat-treating step that includes exposing the Ru metal layer to a H₂-containing gas to remove adsorbed CO surface species from the Ru metal layer;
removing Ru metal nuclei deposited on the first layer, including on a field area and on sidewalls of the first layer in the recessed feature, to selectively form the Ru metal layer on the second layer in the recessed feature, wherein the removing includes exposing the patterned substrate to an etching gas containing ozone; and
performing a second heat-treating step that includes exposing the Ru metal layer to a H₂-containing gas to chemically reduce an exposed surface of the Ru metal layer following the exposure to the etching gas.

20. The method of claim 19, further comprising:
repeating the depositing and removing at least once to increase a thickness of the Ru metal layer in the recessed feature.
